(19) United States
(12) Patent Application Publication
(10) Pub. No.: US 2021/0302320 A1
(43) Pub. Date: Sep. 30, 2021

(54) MOISTURE DETECTION METHOD AND MOISTURE DETECTION SYSTEM

(71) Applicants: MORESCO CORPORATION, Hyogo (JP); NATIONAL UNIVERSITY CORPORATION HOKKAIDO UNIVERSITY, Hokkaido (JP)

(72) Inventors: Toshihiro SHIMADA, Sapporo-shi, Hokkaido (JP); Yoshifumi NAKACHO, Hyogo (JP); Honami NISHIMOTO, Hyogo (JP)

(21) Appl. No.: 17/266,524

(22) PCT Filed: Aug. 8, 2019
(86) PCT No.: PCT/JP2019/031388

§ 371 Date: Feb. 5, 2021

(30) Foreign Application Priority Data
Aug. 24, 2018 (JP) 2018-157810

(51) Int. Cl. G01N 21/77; C09K 11/07

(52) U.S. Cl. CPC G01N 21/77; C09K 2211/1088; G01N 2021/7786; C09K 11/07

(57) ABSTRACT

Provided are a moisture detection method and a moisture detection system which are capable of detecting moisture in a simple manner. A moisture detection method in accordance with the present invention uses a moisture detection system which contains: (A) a substance that reacts with water to produce hydrogen peroxide; and (B) a fluorescent substance that is indirectly excited by hydrogen peroxide to emit light. The moisture detection system may further contain (C) a substance that reacts with hydrogen peroxide to produce a reaction product which excites the fluorescent substance (B) to emit light.

### TECHNICAL FIELD

The present invention relates to a moisture detection system for use in moisture detection and a moisture detection method using the moisture detection system.

### BACKGROUND ART

A barrier film for a film device such as an organic light emitting display is required to have a water vapor permeability of about 10⁻⁶ g/m²/day, and there is a demand for a moisture detection technique that is capable of adding up very small amounts of moisture to detect moisture.

A calcium process, which measures changes in light transmittance and electric resistance, has been known as a method of detecting a very small amount of moisture.

Furthermore, the following method is known as a permeability process method which is capable of detecting, with high sensitivity, an extremely small amount of a component having passed through a to-be-measured film such as a barrier film for a film device (e.g., organic light emitting display) and highly accurately analyzing the component (see Patent Literature 1): a permeability assessment method by which a component having passed through a to-be-measured film is subject to assessment. This method is a permeability assessment method including: a collecting step for collecting a to-be-assessed component which has passed through a to-be-measured film; an adsorbing/immobilizing step involving adsorbing and immobilizing the collected to-be-assessed component on an adsorption-desorption base material; and an analyzing step involving analyzing the to-be-assessed component. The method is arranged such that: in the collecting step, (i) two hermetically sealed spaces are formed in a chamber opposite each other with the to-be-measured film therebetween, the to-be-assessed component is supplied to one of the two hermetically sealed spaces and an inert gas is supplied to the other of the two hermetically sealed spaces so that the two hermetically sealed spaces are equal in pressure, and (ii) the to-be-assessed component which has passed through the to-be-measured film due to the difference between the partial pressures of the to-be-assessed components in the two hermetically sealed spaces is collected in the other of the two hermetically sealed spaces to which the inert gas is supplied; in the adsorbing/immobilizing step, (i) the adsorption-desorption base material, which adsorbs the to-be-assessed component when cooled and which desorbs the to-be-assessed component when the cooling is stopped or when heated, is used, (ii) the collected to-be-assessed component is moved by diffusion or gas circulation and is adsorbed and immobilized on the adsorption-desorption base material which has been cooled, and (iii) evacuation is carried out while the adsorption-desorption base material is in the cooled state; and then, in the analyzing step, the to-be-assessed component is desorbed by stopping the cooling or by heating the adsorption-desorption base material and the to-be-assessed component is analyzed.

### CITATION LIST

### Patent Literature

[Patent Literature 1]

Japanese Patent No. 4759096

### SUMMARY OF INVENTION

### Technical Problem

According to the foregoing calcium process, the measurement takes a long time to perform, and detection sensitivity is not high enough in some cases. Furthermore, with regard to the apparatus disclosed in Patent Literature 1, although the apparatus is capable of assessing the permeability to water vapor in a small amount with high sensitivity by employing a mass spectrometry, the apparatus has a complex structure such as employing a mass spectrometer and a double walled structure. The apparatus disclosed in Patent Literature 1 thus has room for an improvement in terms of detecting moisture in a simple manner. Furthermore, conventional methods are not capable of determining the positions of water molecules on an object under test.

In view of the above, an object of an aspect of the present invention is to provide a moisture detection method and a moisture detection system for use in the moisture detection method each of which makes it possible to detect moisture in a simple manner. Another object of an aspect of the present invention is to provide a moisture detection method that makes it possible to determine the positions of water molecules on an object under test.

### Solution to Problem

In order to attain the above object, a moisture detection method in accordance with an embodiment of the present invention is a method of detecting moisture by detecting light emitted from a moisture detection system, the moisture detection system containing:

(A) a substance that reacts with water to produce hydrogen peroxide; and

(B) a fluorescent substance that is indirectly excited by hydrogen peroxide to emit light.

A moisture detection method in accordance with an embodiment of the present invention may be arranged such that the moisture detection system further contains:

(C) a substance that reacts with hydrogen peroxide to produce a reaction product which excites the fluorescent substance (B) to emit light.

A moisture detection method in accordance with an embodiment of the present invention may be arranged such that the moisture detection system contains a resin.

A moisture detection method in accordance with an embodiment of the present invention may be arranged such that the moisture detection system contains an organic solvent.

In order to attain the above object, a moisture detection system in accordance with an embodiment of the present invention contains:

(A) a substance that reacts with water to produce hydrogen peroxide; and

(B) a fluorescent substance that is indirectly excited by hydrogen peroxide to emit light.

A moisture detection system in accordance with an embodiment of the present invention may further contain:

(C) a substance that reacts with hydrogen peroxide to produce a reaction product which excites the fluorescent substance (B) to emit light.

### Advantageous Effects of Invention

The present invention makes it possible to detect moisture in a simple manner. A moisture detection system emits light upon contact with moisture; therefore, it is possible not only to check for moisture on an object under test but also to determine the position of the moisture. The present invention therefore can be suitably used in, for example, a moisture permeability test on a barrier film for a film device such as an organic light emitting display.

### BRIEF DESCRIPTION OF DRAWINGS

FIG. 1 schematically illustrates an emission detector used in Example 14.

FIG. 2 is a chart showing changes in value of electric current observed by the emission detector used in Example 14.

FIG. 3 schematically illustrates a test piece used in Example 15.

FIG. 4 is an image of a light emitting portion of the test piece observed in Example 15.

### DESCRIPTION OF EMBODIMENTS

The following description will discuss embodiments of the present invention in detail. Note, however, that embodiments of the present invention can be modified variously within the scope of the description. Note that, in the present specification, the scope of the term “water” includes water and water vapor. Also note that any numerical range expressed as “A to B” in the present specification means “not less than A and not more than B” unless otherwise stated.

[1. Moisture Detection System]

A moisture detection system in accordance with an embodiment of the present invention contains: (A) a substance that reacts with water to produce hydrogen peroxide (such a substance is referred to as “component (A)”); and (B) a fluorescent substance that is indirectly excited by hydrogen peroxide to emit light (such a fluorescent substance is referred to as “component (B)”). The moisture detection system may further contain a substance that reacts with hydrogen peroxide to produce a reaction product which excites the fluorescent substance (B) to emit light (such a substance is referred to as “component (C)”).

The component (A) is a substance that reacts with water to produce hydrogen peroxide, and can be, for example, sodium percarbonate, urea hydrogen peroxide, sodium peroxide, or the like. Out of those listed above, sodium percarbonate (Na₂CO₃.1.5H₂O₂) and urea hydrogen peroxide are preferred. In other words, the component (A) is a substance in which hydrogen peroxide contained in the component (A) is replaced by water and thereby the hydrogen peroxide is liberated. Note that the component (A) is not limited to a component composed of one type selected from the substances listed above, and may be composed of a combination of two or more types of substances.

The component (B) is a fluorescent substance, and is preferably a substance that is indirectly excited by hydrogen peroxide to emit light. The term “fluorescent substance that is indirectly excited by hydrogen peroxide” means a fluorescent substance that emits light upon excitation by the product of a reaction between another substance and hydrogen peroxide (such another substance is, for example, the component (C) (described later)).

The component (B) can be a conventionally known fluorescent substance, examples of which include: substances containing a skeleton of naphthalene, naphthoquinone, anthracene, anthraquinone, phenanthrene, tetracene, naphthacene dione, pyridine, quinoline, isoquinoline, indole, isoindole, pyrrole, imidazole, pyrazole, pyrazine, benzimidazole, benzofuran, dibenzofuran, carbazole, acridine, acridone, phenanthridine, xanthine, xanthone, flavone, coumarin, or the like; metal complexes such as a ruthenium tris-bipyridine complex; rare earth compounds such as an europium ATBTA complex; and manganese activated zinc silicate. Note that the component (B) is not limited to a component composed of one type selected from the substances listed above, and may be composed of a combination of two or more types of substances.

The component (C) is a compound that reacts with hydrogen peroxide to produce a reaction product which excites the component (B) to emit light. Note that the component (C) is not limited to one type of substance, and can be composed of two or more types of substances. The reaction product produced by the reaction between the component (C) and hydrogen peroxide is preferably 1,2-dioxetanedione.

Examples of the compound that reacts with hydrogen peroxide to produce 1,2-dioxetanedione include: oxalic acid diesters such as bis(2,4-dichlorophenyl) oxalate, bis(2,4,5-trichlorophenyl) oxalate, bis(2,4,6-trichlorophenyl) oxalate, bis(pentachlorophenyl) oxalate, bis(2,4,5-trichloro-6-carbopentoxyphenyl) oxalate, bis(2,4,5-trichloro-6-carboisopentoxyphenyl) oxalate, bis(2,4,5-trichloro-6-carbobenzoxyphenyl) oxalate, bis(2,4,5-tribromophenyl) oxalate, bis(2,4,6-tribromophenyl) oxalate, bis(2,4-dibromophenyl) oxalate, bis(pentabromophenyl) oxalate, and bis(2,4,5-tribromo-6-carbohexoxyphenyl) oxalate; oxalyl chloride; and tetramethyl-1,2-dioxetane.

The component (A) is preferably sodium percarbonate. The component (B) is preferably a substance that emits light upon excitation by, for example, 1,2-dioxetanedione. The component (B) is more preferably a compound containing a tetracene skeleton, i.e., a tetracene derivative, particularly preferably rubrene.

The proportions of the components (A), (B), and (C) are preferably as follows, in terms of clear fluorescence emission.

The proportion of the component (A) contained in the moisture detection system is preferably 5 parts by mass to 50 parts by mass, more preferably 10 parts by mass to 25 parts by mass, relative to 1 part by mass of the component (B) contained in the moisture detection system.

The proportion of the component (C) contained in the moisture detection system is preferably 1 part by mass to 50 parts by mass, more preferably 2 parts by mass to 20 parts by mass, relative to 1 part by mass of the component (B) contained in the moisture detection system.

In an embodiment of the present invention, the moisture detection system preferably contains a catalyst in order to achieve greater fluorescence. The catalyst can be, for example, a carboxylate or the like. The moisture detection system may contain one type of catalyst or two or more types of catalysts.

In a case where the moisture detection system in accordance with an embodiment of the present invention contains a catalyst, the proportion of the catalyst contained in the moisture detection system is preferably 0.01 parts by mass to 5 parts by mass, more preferably 0.02 parts by mass to 1 part by mass, relative to 1 part by mass of the component (B) contained in the moisture detection system.

The carboxylate is preferably a compound represented by the following general formula: R—COOM or (R—COO)₂M (where R is a hydrocarbon group that optionally contains a hydroxy group or a halogen atom, and M is a mono- or divalent metal atom).

Example of the carboxylate include: salicylates such as sodium salicylate, potassium salicylate, lithium salicylate, magnesium salicylate, and ammonium salicylate; chlorosalicylates such as sodium 3-chlorosalicylate, sodium 5-chlorosalicylate, lithium 3-chlorosalicylate, lithium 5-chlorosalicylate, and magnesium 3-chlorosalicylate; dichlorosalicylates such as lithium 3,5-dichlorosalicylate and magnesium 3,5-dichlorosalicylate; trichlorosalicylates such as lithium 3,5,6-trichlorosalicylate and magnesium 3,5,6-trichlorosalicylate; bromosalicylates such as sodium 5-bromosalicylate; alkyl salicylates such as lithium 5-tert-butyl salicylate and magnesium 5-tert-butyl salicylate; benzoates; chlorobenzoates such as lithium 2-chlorobenzoate; trichlorobenzoates; acetates; trifluoroacetates such as sodium trifluoroacetate and lithium trifluoroacetate; and rubidium acetate. Out of those listed above, salicylates are preferred, and sodium salicylate is particularly preferred.

In an embodiment of the present invention, the moisture detection system can further contain any of the following optional components depending on the properties or purpose of use: water-free organic solvents, binders (a resin or a precursor thereto), monomers, polymerization initiators, curing aids (crosslinking agents), dispersing agents, and supports.

There is no particular limitation on the form of the moisture detection system in accordance with an embodiment of the present invention. The moisture detection system may be a mixture of the components or may be matter in which the components are not mixed. In a case where the moisture detection system is a mixture, the mixture may be a solid mixture or a liquid mixture. The moisture detection system may be a composite composed of (i) a base material and (ii) a layer of a solid mixture or a layer of a liquid mixture which is provided on at least part of the surface of the base material. Note that the solid mixture may be a mixture composed of the components (such as mixed powder) or may be a molded object having a definite shape. In the latter case, the mixture may be one that is obtained by allowing a liquid mixture to solidify. As described above, the moisture detection system in accordance with an embodiment of the present invention can be a solid mixture or a liquid mixture; however, each mixture is preferably a mixture obtained by uniformly mixing the main components and the like.

In a case where the moisture detection system is composed of mixed powder, a preferred aspect is a mixture composed of main components and the like which are all solid. Also in a case where the moisture detection system contains some other component, such other component is preferably a solid material.

On the other hand, in a case where the moisture detection system is composed of a molded object, the molded object can be, for example, a molded object such as a sheet obtained by subjecting the mixed powder to pressing or the like, a molded object such as a film formed using a resin or a precursor thereto (e.g., monomer composed of a polymerizable unsaturated compound, a curable compound), or the like. Note that the molded object such as a film may be joined to the surface of a base material to form a composite (film-attached base material, described later).

The solid mixture may contain a resin. The resin may be a thermoplastic resin (including thermoplastic elastomer) or a curable resin. Examples of the thermoplastic resin include olefin-based resins, acrylic-based resins, styrene-based resins (rubber-reinforced vinyl-based resin, hydrogenated styrene-based thermoplastic elastomer, and the like), ethylene-vinyl acetate copolymers, polyester, polyamide, polycarbonate, and the like. The curable resin can be composed of a crosslinkable resin derived from a multifunctional (meth)acrylate, an unsaturated polyester, epoxy resin, or the like.

In a case where the solid mixture is a molded object containing a resin, the main components in the molded object are preferably present in the vicinity of the surface of the molded object, particularly preferably exposed on the surface of the molded object, in terms of light emission.

Next, in a case where the moisture detection system is a liquid mixture, the main components and the like are preferably dispersed in a medium. Note that the main components and the like may be partially dissolved in the medium.

The medium is not particularly limited, and may be composed of a single component or two or more components. A preferred medium is an organic solvent; however, the medium may be: a liquid monomer composed of a polymerizable unsaturated compound; or a curable compound such as a multifunctional (meth)acrylate, an unsaturated polyester, or epoxy resin.

The medium can be a medium composed of an organic solvent and a monomer or can be a medium composed of an organic solvent and a curable compound.

Examples of the organic solvent that can be used include hydrocarbons, alcohols, esters, ethers, ketones, and carboxylic acids.

A preferred aspect of the liquid mixture can be a mixture containing (i) a resin or a precursor thereto, (ii) an aid, and/or the like. The resin can preferably be the foregoing thermoplastic resin (including thermoplastic elastomer). The precursor to the resin can preferably be, for example: a monomer composed of a polymerizable unsaturated compound such as an aromatic vinyl compound, a vinyl cyanide compound, an unsaturated acid, a (meth)acrylic acid ester compound, or a polymerizable unsaturated compound containing an amino group; a curable compound such as a multifunctional (meth)acrylate, an unsaturated polyester, or epoxy resin; and/or the like. The aid can be, for example, a polymerization initiator, a curing aid (crosslinking agent), a dispersing agent, and/or the like.

Particularly preferred aspects of the liquid mixture are, for example, as follows.

(1) A liquid mixture containing main components (which mean “component (A) and component (B)” or “component (A), component (B), and component (C)” in the present specification), a catalyst, and an organic solvent

(2) A liquid mixture containing main components, a catalyst, and a curable compound

(3) A liquid mixture containing main components, a catalyst, a thermoplastic resin, and an organic solvent

(4) A liquid mixture containing main components, a catalyst, and a monomer

The liquid mixture (1) can be used as-is in the form of a liquid that contains the main components and the catalyst. The liquid mixture (1) can also be applied onto a base material and then, for example, dried to evaporate the organic solvent, whereby the liquid mixture (1) can also be used to form an article which is composed of (i) the base material and (ii) the mixture of the main components and the catalyst impregnated in the surface of the base material.

The liquid mixture (2) preferably further contains a polymerization initiator or a curing aid (crosslinking agent) in order to form a molded object such as a film. Such a liquid mixture can be, for example, applied onto a base material to form a coating and the coating can be allowed to cure (cure at room temperature, heat curing, photo-curing etc.). This makes it possible to obtain a film-attached base material (composite) which includes: a matrix composed of a cured resin obtained by crosslinking the curable compound; and the main components and the catalyst which are contained in a uniformly dispersed state in the matrix. Furthermore, by filling such a liquid mixture into, for example, a mold with a cavity of a definite shape and heating the liquid mixture, it is possible to obtain a molded object composed of: a matrix composed of a cured resin obtained by crosslinking the curable compound; and the main components and the catalyst which are contained in a uniformly dispersed state in the matrix.

The liquid mixture (3) is preferably a composition in which: the thermoplastic resin is dissolved in the organic solvent to form a solution; and the main components and the catalyst are dispersed in the solution, in order to form a molded object such as a film. By applying such a liquid mixture onto, for example, a base material to form a coating and drying the coating, it is possible to obtain a film-attached base material (composite) that includes: a matrix composed of the thermoplastic resin; and the main components and the catalyst which are contained in a uniformly dispersed state in the matrix.

The liquid mixture (4) preferably further contains a polymerization initiator. By applying such a liquid mixture onto, for example, a base material to form a coating and drying the coating, it is possible to obtain a film-attached base material (composite) that includes: a matrix composed of a polymer obtained by polymerizing the monomer; and the main components and the catalyst which are contained in a uniformly dispersed state in the matrix.

Note that a material for the base material for use in each of the foregoing aspects may be an organic material, an inorganic material, or both of them. Also note that the base material can be in the form of a film, a sheet, a container, a pipe, an indefinite shape, or the like. The base material may be at least partially air permeable such that air can pass through the base material from one side to the other.

As has been described, the moisture detection system in accordance with an embodiment of the present invention can be in the form of a solid or a liquid. In either case, fluorescence can be caused merely by allowing, for example, a small water droplet to make contact with the moisture detection system.

Furthermore, fluorescence can be confirmed by visual checking or by use of a photodetector such as a photodiode, a photomultiplier tube, or a highly sensitive camera, preferably under conditions in which light is blocked. Note that, when carrying out the detection of fluorescence by a photodetector, a current detector can be used together with the photodetector.

In an embodiment of the present invention, a preferred configuration of a moisture detection system can be, for example, a moisture detection system that contains sodium percarbonate, a tetracene derivative, and an oxalic acid diester. Once the moisture detection system and water have made contact with each other, first, hydrogen peroxide contained in the sodium percarbonate (i.e., component (A)) and water substitute for each other and the hydrogen peroxide is liberated. Next, the liberated hydrogen peroxide reacts with the oxalic acid diester (i.e., component (C)) to produce a reaction product, i.e., 1,2-dioxetanedione (however, in a case where the reaction product is low in stability, a product resulting from the degradation of the reaction product), which excites the tetracene derivative (i.e., component (B)), thereby allowing the tetracene derivative to emit fluorescence. In this case, the 1,2-dioxetanedione is in its excited state, this excitation energy excites the tetracene derivative (i.e., component (B)), and the excited tetracene derivative emits light as it returns to the ground state. The color of light emitted depends on the type of component (B). In a case where the tetracene derivative is rubrene, the color of the light is yellow.

As described above, once the moisture detection system and water have made contact with each other, reactions proceed. This causes a change in the composition of the moisture detection system. Therefore, in a case where the moisture detection system is stored until use, the moisture detection system should be stored in an atmosphere in which neither water nor water vapor is present.

[2. Moisture Detection Method]

A moisture detection method in accordance with an embodiment of the present invention is a method of, with use of the moisture detection system described in the section “1. Moisture detection system”, detecting moisture by detecting light emitted by the moisture detection system. The moisture detection system has already been described in the section “1. Moisture detection system”, and therefore descriptions therefor are omitted here.

In the moisture detection method in accordance with an embodiment of the present invention, the moisture detection system emits light upon contact with moisture. Therefore, by detecting this light, it is possible to determine whether or not an object under test contains moisture. Furthermore, it is possible to determine which portion of the object under test is emitting light, making it possible to determine which portion of the object under test has the moisture.

In the moisture detection method in accordance with an embodiment of the present invention, for example, the moisture detection system for use in the method is selected appropriately from the following: a solid mixture, a liquid mixture, and a composite (an article having, on its surface, a mixture of components (A), (B), and/or the like), depending on the type or structure of object to be tested. The object to be tested is not particularly limited, and may be an article that is known to contain moisture or an article that is unknown whether it contains moisture or not.

The moisture detection method in accordance with an embodiment of the present invention can be used in, for example, evaluating a barrier film product. Specifically, the moisture detection method can be used to check whether or not a prepared barrier film has a part (opening, cracking) through which a gas (water vapor) can pass from one side to the other. When water vapor is sprayed onto the lower surface of a barrier film which has a moisture detection system disposed or applied on or above its upper surface, if there is an opening or cracking in the barrier film, water vapor that has passed through the opening or cracking will make contact with main components contained in the moisture detection system. This allows the moisture detection system present on the opening or cracking to emit light, making it possible to determine the position of the opening or cracking in the barrier film.

The moisture detection method in accordance with an embodiment of the present invention can be used not only to evaluate a barrier film product but also to detect moisture leakage through a sealer after parts are assembled into a device.

### EXAMPLES

The following description will more specifically discuss the present invention based on Examples. Note, however, that the present invention is not limited to such Examples.

Main components used to prepare a moisture detection system in Examples are the following components (A), (B), and (C): sodium percarbonate was used as a component (A); rubrene was used as a component (B); and bis(2,4,6-trichlorophenyl) oxalate was used as a component (C).

[1. Preparation and Evaluation of Moisture Detection System (1)]

### Examples 1 to 5

The above-stated main components, a catalyst (sodium salicylate), and an organic solvent (methanol, toluene, acetone, hexane or dimethyl phthalate) were mixed to have the mass ratio shown in Table 1. In this way, a moisture detection system composed of a dispersion was prepared.

Next, the dispersion (moisture detection system) was put in a container, 10 parts by mass of water was added to the dispersion, and the dispersion was shaken to obtain a mixed liquid. Then, the manner in which the obtained mixed liquid as a whole emits light was checked in a darkroom. The results are also shown in Table 1. Note that the results of the checking of light emission were evaluated based on the following criteria. The same applies to the other Examples.

“3”: Strong light emission was observed.

“2”: Weak light emission was observed.

“1”: Very weak light emission was observed.

TABLE 1

| | | | | | | [parts |
|---|---|---|---|---|---|---|
| | | | | | | by |
| | | | | | | mass] |
| | | Ex- | Ex- | Ex- | Ex- | Ex- |
| | | ample | ample | ample | ample | ample |
| | | 1 | 2 | 3 | 4 | 5 |
| Component (A) | | 13 | 13 | 13 | 13 | 13 |
| Component (B) | | 1 | 1 | 1 | 1 | 1 |
| Component (C) | | 3 | 3 | 3 | 3 | 3 |
| Catalyst | | 1 | 1 | 1 | 1 | 1 |
| Organic | Methanol | 333 | — | — | — | — |
| solvent | Toluene | — | 500 | — | — | — |
| | Acetone | — | — | 500 | — | — |
| | Hexane | — | — | — | 333 | — |
| | Dimethyl | — | — | — | — | 333 |
| | phthalate | | | | | |

| | | | | | |
|---|---|---|---|---|---|
| Result of checking | 1 | 3 | 2 | 1 | 3 |
| of light emission | | | | | |

### Examples 6 to 8

The above-stated main components, a catalyst (sodium salicylate), an ultraviolet curable resin (acrylate resin “IRR 214-K” [main component: tricyclodecane dimethanol diacrylate] manufactured by DAICEL-ALLNEX LTD., acrylate resin “EBECRYL 110” [main component: ethoxylated phenyl acrylate] manufactured by DAICEL-ALLNEX LTD., or methacrylate resin “NK ester DCP” [main component: tricyclodecane dimethanol dimethacrylate] manufactured by SHIN-NAKAMURA CHEMICAL Co., Ltd.), and a cationic photopolymerization initiator “IRGACURE 184A” manufactured by BASF were mixed to have the mass ratio shown in Table 2. In this way, a moisture detection system in the form of a liquid was prepared. Note that the components (A), (B), and (C) and the catalyst were weighed out, mixed, and pulverized before use.

Next, the moisture detection system was applied onto the surface of a mold release film to form a coating, and the coating was irradiated with ultraviolet light with use of a metal halide lamp to form a cured film. The cured film was removed from the mold release film. In this way, a cured film (moisture detection system) having a thickness of about 50 μm was prepared.

Then, water was dropped onto the surface of the cured film (moisture detection system), and the manner in which the cured film emits light was checked in a darkroom. The results are also shown in Table 2.

TABLE 2

| | | | | [parts |
|---|---|---|---|---|
| | | | | by mass] |
| | | Example | Example | Example |
| | | 6 | 7 | 8 |
| Component (A) | | 13 | 13 | 13 |
| Component (B) | | 1 | 1 | 1 |
| Component (C) | | 3 | 3 | 3 |
| Catalyst | | 1 | 1 | 1 |
| Ultra- | IRR214-K | 166 | — | — |
| violet | EBECRYL | — | 166 | — |
| curable | 110 | | | |
| resin | NK ester | — | — | 166 |
| | DCP | | | |

| | | | |
|---|---|---|---|
| Cationic photo- | 16 | 16 | 16 |
| polymerization | | | |
| initiator | | | |
| Result of checking | 1 | 1 | 2 |
| of light emission | | | |

### Example 9

A methyl methacrylate-butyl acrylate copolymer “LA2140” manufactured by KURARAY Co., Ltd. (thermoplastic resin) was dissolved in toluene to obtain a polymer solution. Next, the polymer solution, the above-stated main components, and a catalyst (sodium salicylate) were mixed to prepare a moisture detection system in the form of a liquid (see Table 3). Note that the components (A), (B), and (C) and the catalyst were weighed out, mixed, and pulverized before use.

Next, the moisture detection system was applied onto the surface of a mold release film, and dried to form a thermoplastic resin film. The thermoplastic resin film was removed from the mold release film. In this way, a thermoplastic resin film (moisture detection system) having a thickness of about 50 μm was prepared.

Then, 10 parts by mass of water was dropped onto the surface of the thermoplastic resin film (moisture detection system), and the manner in which the thermoplastic resin film emits light was checked in a darkroom. The results are also shown in Table 3.

### Example 10

The same operations as described in Example 9 were carried out, except that a styrene-ethylene-propylene copolymer “SEPTON 2002” manufactured by KURARAY Co., Ltd. was used instead of the methyl methacrylate-butyl acrylate copolymer. In this way, a thermoplastic resin film (moisture detection system) was prepared.

Then, water was dropped onto the surface of the thermoplastic resin film (moisture detection system), and the manner in which the thermoplastic resin film emits light was checked in a darkroom, in the same manner as Example 9. The results are also shown in Table 3.

### Example 11

The same operations as described in Example 9 were carried out, except that an ethylene-vinyl acetate copolymer “ULTRATHENE 760” manufactured by Tosoh Corporation was used instead of the methyl methacrylate-butyl acrylate copolymer. In this way, a thermoplastic resin film (moisture detection system) was prepared.

Then, water was dropped onto the surface of the thermoplastic resin film (moisture detection system), and the manner in which the thermoplastic resin film emits light was checked in a darkroom, in the same manner as Example 9. The results are also shown in Table 3.

### Example 12

The same operations as described in Example 9 were carried out, except that a maleic anhydride-grafted styrene-ethylene-butylene copolymer “Kraton FG1924G” manufactured by Kraton Polymers was used instead of the methyl methacrylate-butyl acrylate copolymer. In this way, a thermoplastic resin film (moisture detection system) was prepared.

Then, water was dropped onto the surface of the thermoplastic resin film (moisture detection system), and the manner in which the thermoplastic resin film emits light was checked in a darkroom, in the same manner as Example 9. The results are also shown in Table 3.

### Example 13

The same operations as described in Example 9 were carried out, except that a polylactic acid “Vercet A-1000” manufactured by NatureWorks LLC was used instead of the methyl methacrylate-butyl acrylate copolymer. In this way, a thermoplastic resin film (moisture detection system) was prepared.

Then, water was dropped onto the surface of the thermoplastic resin film (moisture detection system), and the manner in which the thermoplastic resin film emits light was checked in a darkroom, in the same manner as Example 9. The results are also shown in Table 3.

TABLE 3

| | | | | | | [parts |
|---|---|---|---|---|---|---|
| | | Ex- | Ex- | Ex- | Ex- | by mass] |
| | | ample | ample | ample | ample | Example |
| | | 9 | 10 | 11 | 12 | 13 |
| Component (A) | | 13 | 13 | 13 | 13 | 13 |
| Component (B) | | 1 | 1 | 1 | 1 | 1 |
| Component (C) | | 3 | 3 | 3 | 3 | 3 |
| Catalyst | | 1 | 1 | 1 | 1 | 1 |
| Organic | Toluene | 166 | 333 | 500 | 1000 | 1333 |
| solvent | | | | | | |
| Thermo- | LA2140 | 166 | — | — | — | — |
| plastic | SEPTON | — | 166 | — | — | — |
| resin | 2002 | | | | | |
| | ULTRA- | — | — | 166 | — | — |
| | THENE | | | | | |
| | 760 | | | | | |
| | FG1924G | — | — | — | 166 | — |
| | A-1000 | — | — | — | — | 166 |

| | | | | | |
|---|---|---|---|---|---|
| Result of checking | 3 | 2 | 3 | 2 | 3 |
| of light emission | | | | | |

[2. Preparation and Evaluation of Moisture Detection System (2)]

### Example 14

A methyl methacrylate-butyl acrylate copolymer “LA2140” manufactured by KURARAY Co., Ltd. (thermoplastic resin) was dissolved in toluene to obtain a polymer solution. Next, the polymer solution, the above-stated main components, and a catalyst (sodium salicylate) were mixed to prepare a moisture detection system in the form of a liquid (see Table 4). Note that the components (A), (B), and (C) and the catalyst were weighed out, mixed, and pulverized before use.

TABLE 4

| | | [parts |
|---|---|---|
| | | by mass] |
| | | Example 14 |
| Component (A) | | 13 |
| Component (B) | | 1 |
| Component (C) | | 3 |
| Catalyst | | 1 |
| Organic | Toluene | 166 |
| solvent | | |
| Thermo- | LA2140 | 166 |
| plastic | | |
| resin | | |

Next, the moisture detection system was applied onto the surface of a mold release film, and dried to form a thermoplastic resin film. The thermoplastic resin film was removed from the mold release film. In this way, a thermoplastic resin film (moisture detection system) having a thickness of about 50 μm was prepared.

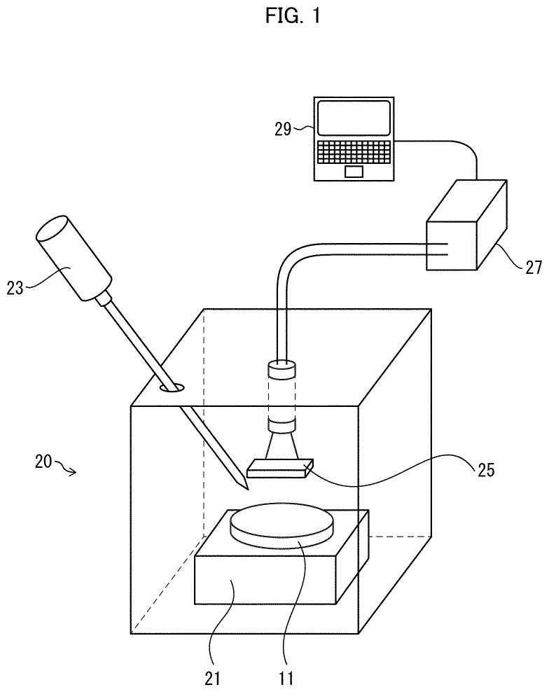

Then, water was dropped onto the surface of the thermoplastic resin film (moisture detection system), and light emission detection was carried out in the following manner with use of an emission detector illustrated in FIG. 1.

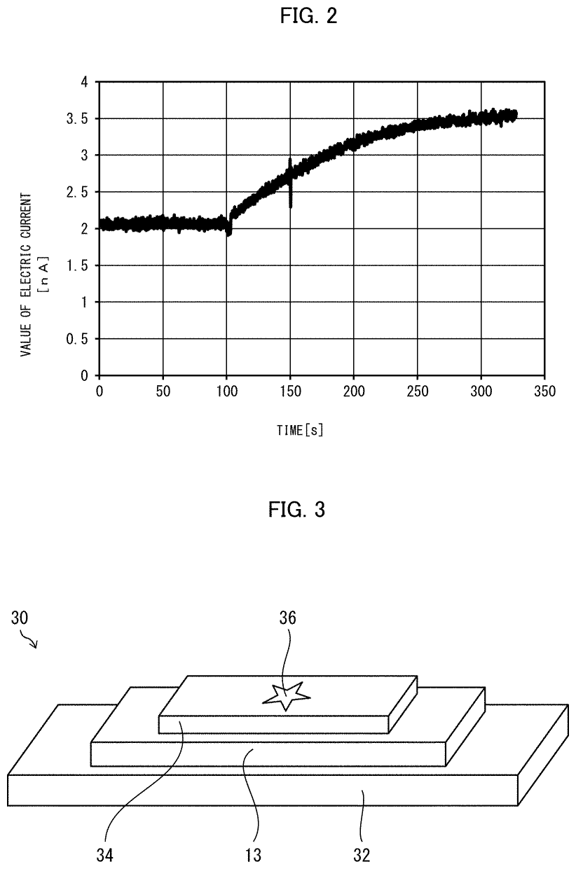

FIG. 1 schematically illustrates an emission detector 20. First, in the emission detector 20, a moisture detection system 11 composed of the thermoplastic resin film was placed on a sample stage 21 in a light-blocking container (no sign is assigned in FIG. 1). In this situation, water (3 parts by mass) was dropped onto the surface of the moisture detection system 11 with use of a syringe 23. Then, the value of electric current that was generated in a photodiode 25 (its sensitive wavelengths are 320 nm to 1100 nm) was observed, and light emission detection was carried out based on changes in the value of electric current. Note that the distance between the moisture detection system and the photodiode 25 was about 25 mm. In this experiment using the emission detector 20, the measurement of the value of electric current was started concurrently with the issuance of an instruction by a computer 29 to start the measurement, and, 100 seconds after that, water was dropped from the syringe 23 and whether the value of electric current would change or not was checked. The results are shown in FIG. 2.

FIG. 2 shows that the value of electric current started to increase at the same time as the dropping of water onto the surface of the thermoplastic resin film (moisture detection system). This demonstrates that the thermoplastic resin film emitted light immediately after contact with water.

[3. Preparation and Evaluation of Moisture Detection System (3)]

### Example 15

A methyl methacrylate-butyl acrylate copolymer “LA2140” manufactured by KURARAY Co., Ltd. (thermoplastic resin) was dissolved in toluene to obtain a polymer solution. Next, the polymer solution was applied onto the surface of a mold release film, and dried to form a thermoplastic resin film. The thermoplastic resin film was removed from the mold release film. In this way, a thermoplastic resin film having a thickness of about 50 μm was prepared.

Next, the above-stated main components, a catalyst (sodium salicylate), and dimethyl phthalate in amounts shown in Table 6 were mixed to prepare a dispersion. Note that the components (A), (B), and (C) and the catalyst were weighed out, mixed, and pulverized before use.

Then, the dispersion was applied onto the surface of the thermoplastic resin film, and dried (dimethyl phthalate was removed). In this way, a composite film (moisture detection system) was obtained.

TABLE 5

| | | [parts |
|---|---|---|
| | | by mass] |
| | | Example 15 |
| Component (A) | | 13 |
| Component (B) | | 1 |
| Component (C) | | 3 |
| Catalyst | | 1 |
| Organic | Dimethyl | 33 |
| solvent | phthalate | |
| | Toluene | 166 |
| Thermo- | LA2140 | 166 |
| plastic | | |
| resin | | |

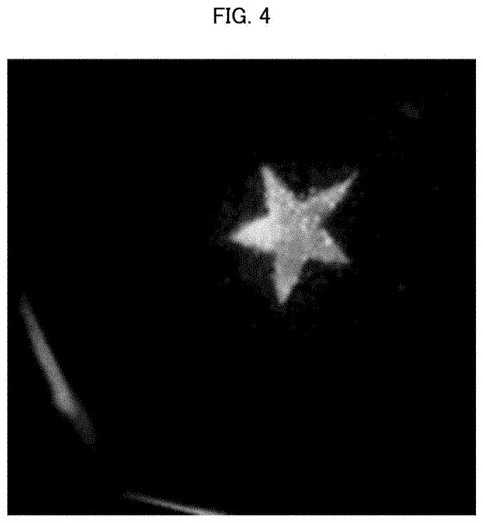

Next, a moisture detection system 13 composed of the composite film was used to prepare a test piece 30 illustrated in FIG. 3. Specifically, the composite film (moisture detection system) 13 was placed on a substrate 32 composed of glass, and then a transparent PET film 34 having a star-shaped opening 36 was placed on the surface, impregnated with the main components and the catalyst, of the composite film (moisture detection system) 13. In this way, the test piece 30 was prepared. Then, the test piece 30 was allowed to stand in conditions in which humidity was 80%, and, immediately after that, whether the exposed portion of the surface impregnated with the main components and the catalyst was emitting light was checked through the opening in a darkroom. As a result, star-shaped light emission was observed as shown in FIG. 4.

### INDUSTRIAL APPLICABILITY

A moisture detection system and a moisture detection method using the moisture detection system in accordance with the present invention make it possible not only to detect moisture on an object under test in a simple manner but also to determine a portion of the object under test which portion contains moisture. The present invention therefore can be used in a moisture permeability test on a product such as a barrier film.

### REFERENCE SIGNS LIST

11: moisture detection system (resin film)
13: moisture detection system (composite film)
20: emission detector
21: sample stage
23: syringe
25: photodiode
27: source meter
29: computer
30: test piece
32: substrate
34: transparent PET film
36: star-shaped opening

1. A method of detecting moisture by detecting light emitted from a moisture detection system,
the moisture detection system comprising:
(A) a substance that reacts with water to produce hydrogen peroxide; and
(B) a fluorescent substance that is indirectly excited by hydrogen peroxide to emit light.

2. The method as set forth in claim 1, wherein the moisture detection system further comprises:
(C) a substance that reacts with hydrogen peroxide to produce a reaction product which excites the fluorescent substance (B) to emit light.

3. The method as set forth in claim 1, wherein the moisture detection system comprises a resin.

4. The method as set forth in claim 1, wherein the moisture detection system comprises an organic solvent.

5. A moisture detection system comprising:
(A) a substance that reacts with water to produce hydrogen peroxide; and
(B) a fluorescent substance that is indirectly excited by hydrogen peroxide to emit light.

6. The moisture detection system as set forth in claim 5, further comprising:
(C) a substance that reacts with hydrogen peroxide to produce a reaction product which excites the fluorescent substance (B) to emit light.
